(19) United States
(12) Patent Application Publication
(10) Pub. No.: US 2016/0196062 A1
(43) Pub. Date: Jul. 7, 2016

(54) MEMORY SYSTEM

(71) Applicant: Kabushiki Kaisha Toshiba, Minato-ku (JP)

(72) Inventors: Daisuke NAKATA, Kamakura (JP); Hironori KATSURAYAMA, Yokohama (JP); Shigefumi IRIEDA, Yokohama (JP)

(73) Assignee: Kabushiki Kaisha Toshiba, Minato-ku (JP)

(21) Appl. No.: 14/644,638

(22) Filed: Mar. 11, 2015

Related U.S. Application Data
(60) Provisional application No. 62/099,664, filed on Jan. 5, 2015.

(51) Int. Cl. G06F 3/06; G11C 16/34

(52) U.S. Cl. CPC G06F 3/061; G11C 16/3495; G06F 3/0688; G06F 3/0655

(57) ABSTRACT

According to one embodiment, a memory system is connectable to an external device. The memory system includes a non-volatile memory, a control unit, and a temperature detector. The control unit is configured to manage the count information relating to a count of writes or a count of erases in the non-volatile memory in each predetermined region in the non-volatile memory. The temperature detector is configured to detect a first temperature in the memory system. The control unit is configured to add a value to the count information. The added value corresponds to the count of writes or the count of erases occurred after a previous update of the count information and the first temperature. The control unit is configured to determine a degree of deterioration of the non-volatile memory based on the count information after the addition.

### CROSS-REFERENCE TO RELATED APPLICATIONS

This application is based upon and claims the benefit of priority from U.S. Provisional Application No. 62/099,664, filed on Jan. 5, 2015; the entire contents of which are incorporated herein by reference.

### FIELD

Embodiments described herein relate generally to a memory system.

### BACKGROUND

A memory system that includes a non-volatile memory is likely to increase a Bit Error Rate as a count of writes/erases increases. In view of this, the conventional memory system measures the count of writes/erases and detects a deterioration of a property of the non-volatile memory.

However, it has been difficult to accurately determine the deterioration of the property by simply determining the deterioration of the property based on only the count of writes/erases. In view of this, accurately determining the deterioration of the property of the non-volatile memory has been desired.

### BRIEF DESCRIPTION OF THE DRAWINGS

FIG. 1 is a drawing illustrating a configuration of a memory system according to an embodiment;

FIG. 2 is a drawing illustrating another configuration of the memory system according to the embodiment;

FIG. 3 is a flowchart illustrating a procedure for an operating process when the memory system according to the embodiment manages W/E count information;

FIG. 4 is a drawing for describing a relationship between a NAND temperature and a degree of deterioration of a NAND memory;

FIG. 5 is a flowchart illustrating a procedure for an operating process when the memory system according to the embodiment changes a NAND parameter;

FIG. 6 is a drawing illustrating exemplary corresponding information that makes an amount of ECC correction correspond to the NAND parameter; and

FIG. 7 is a drawing illustrating exemplary corresponding information that makes an ability of the NAND memory correspond to the NAND parameter.

### DETAILED DESCRIPTION

According to this embodiment, a memory system is provided. The memory system is connectable to an external device. The memory system includes a non-volatile memory, a controller, and a temperature detector. The controller controls the non-volatile memory according to a request from the external device. The controller manages count information in each predetermined region in the non-volatile memory. The count information relates to a count of writes or a count of erases in the non-volatile memory. The temperature detector detects a first temperature in the memory system. The controller adds a value to the count information. The added value corresponds to the count of writes or the count of erases occurred after a previous update of the count information and the first temperature. Based on the count information after the addition, the degree of deterioration of the non-volatile memory is determined.

Exemplary embodiments of the memory system will be explained below in detail with reference to the accompanying drawings. The present invention is not limited to the following embodiments.

### Embodiment

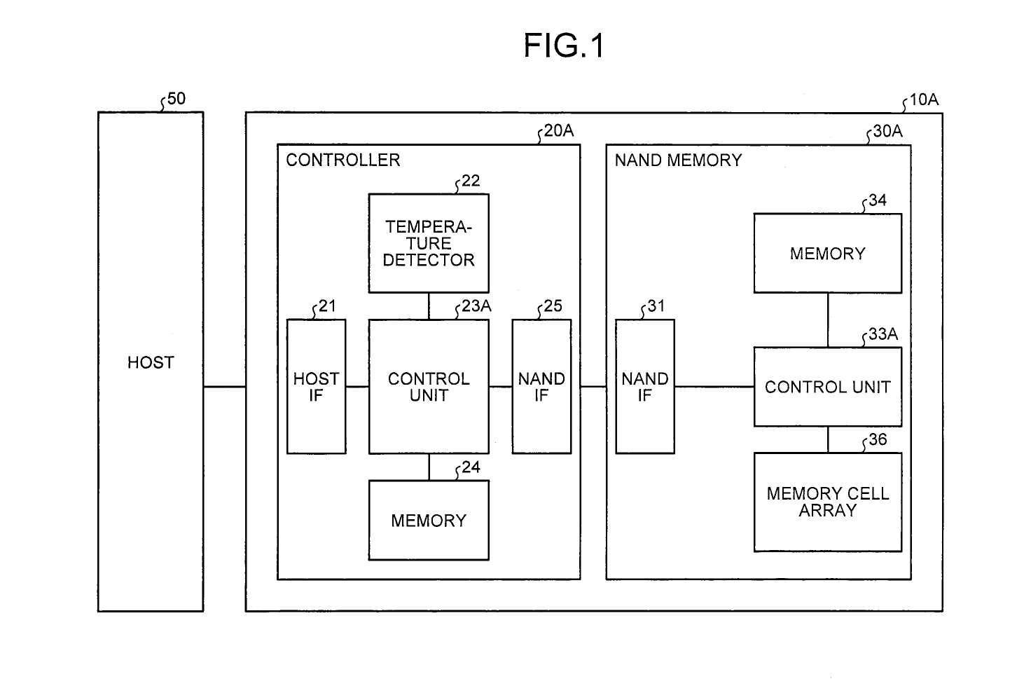

FIG. 1 is a drawing illustrating a configuration of a memory system according to an embodiment. This embodiment describes a case where the memory system is a Solid State Drive (SSD) 10A. However, the memory system may be an embedded MultiMedia Card (eMMC™) device or a similar device.

When a NAND memory 30A writes or erases any data (such as user data and management data), the SSD 10A of this embodiment detects the temperature of a NAND memory 30A. Then, the SSD 10A weights the count of writes/erases corresponding to the detected temperature and counts up the count information regarding the count of writes/erases (the W/E count information described later).

The SSD 10A is coupled to an external device such as a host 50. The SSD 10A includes a controller 20A and the NAND memory (NAND flash-memory) 30A. The NAND memory 30A is an exemplary non-volatile memory of an additionally record type.

Upon reception of a write command from the host 50, the SSD 10A writes the user data (write data) corresponding to the write command to the NAND memory 30A at a predetermined timing. Upon reception of an erase command from the host 50, the SSD 10A erases the user data corresponding to the erase command from the NAND memory 30A. Upon reception of a read command from the host 50, the SSD 10A reads the user data corresponding to the read command from the NAND memory 30A.

The controller 20A is configured by a semiconductor chip (SoC: System on a Chip) and a similar component. The controller 20A controls the NAND memory 30A in response to a request from the host 50. The controller 20A controls data transfer between the host 50 and the NAND memory 30A or a similar operation.

The controller 20A of this embodiment determines the degree of deterioration of the NAND memory 30A based on a temperature when writing/erasing the user data or similar data to/from the NAND memory 30A and the W/E count information.

The controller 20A includes a host IF (interface) 21, a temperature detector 22, a control unit 23A, a memory 24, and a NAND IF 25. In the controller 20A, the above-described respective configuration members are coupled via a bus or a similar component.

The host IF 21 has a function as a reception unit that accepts the write command, the read command, the erase command, or a similar command, which is transmitted from the host 50. The host IF 21 receives data transmitted from the host 50 (the write command, the read command, the erase command, the user data, or similar data). The host IF 21 transmits the user data (the read data) or similar data to the host 50. The NAND IF 25 transmits the user data or similar data in the controller 20A to the NAND memory 30A and receives the user data or similar data transmitted from the NAND memory 30A.

The memory 24 is a buffer that temporarily stores the user data or similar data transmitted from the host 50 upon acceptance of the write command. The memory 24 is configured using, for example, a memory retention circuit. The user data or similar data stored in the memory 24 is written to the NAND memory 30A at a predetermined timing.

The temperature detector 22 detects the temperature of the NAND memory 30A. The temperature detector 22 is formed using, for example, a temperature sensing circuit such as a thermal circuit. The temperature detector 22, for example, detects a junction temperature when performing a write operation or an erase operation. The junction temperature, which is detected by the temperature detector 22, is a temperature at a coupling portion of lead wires in the controller 20A and members configuring the controller 20A. The temperature detector 22 may detect the temperature of the NAND memory 30A at the timing other than the write operation or the erase operation.

At occurrence of the write operation or the erase operation on the user data or similar data in the NAND memory 30A, the temperature detector 22 of this embodiment detects the temperature of the NAND memory 30A (near the NAND memory 30A) in accordance with an instruction from the control unit 23A.

The temperature detector 22, for example, detects a temperature in the SSD 10A, such as the NAND memory 30A, (hereinafter referred to as a NAND temperature) when writing the user data or similar data in the controller 20A to a memory 34, which will be described later. The temperature detector 22 may detect the NAND temperature when writing the user data or similar data in the memory 34 to a memory cell array 36, which will be described later. The temperature detector 22 may detect the NAND temperature when erasing the user data or similar data from the inside of the memory cell array 36. The temperature detector 22 transmits a detection result of the temperature (the NAND temperature) to the control unit 23A.

The control unit 23A controls the host IF 21, the temperature detector 22, the memory 24, and the NAND IF 25. The control unit 23A manages the W/E count information in the NAND memory 30A (the information corresponding to the count of writes or the information corresponding to the count of erases) in each predetermined region in the NAND memory 30A. The W/E count information is a value counted up based on the NAND temperature detected at the write operation or the erase operation.

At occurrence of an operation of writing the user data or similar data in the memory 24 to the memory cell array 36 or an operation of erasing the user data or similar data in the memory cell array 36 (hereinafter referred to as a write/erase operation), the control unit 23A transmits a temperature detection instruction to the temperature detector 22. The write/erase operation occurs when transmitting the write/erase command from the host 50 and performing a garbage collection (a compaction) or a similar operation.

Upon reception of the NAND temperature from the temperature detector 22, the control unit 23A weights the count of writes/erases and then updates the W/E count information. In other words, the control unit 23A weights a value to be incremented to the W/E count information corresponding to the detected temperature. Specifically, the control unit 23A weights the count of writes/erases based on the NAND temperature and adds the weighted count of writes/erases to the W/E count information.

The W/E count information indicates a value regarding the count of writes or the count of erases in a NAND memory 30. The W/E count information is to manage the count of writes or the count of erases in the NAND memory 30 in each predetermined region in the NAND memory 30A. For example, the W/E count information may be managed in units of pages in the NAND memory 30A or may be managed in units of blocks.

The control unit 23A may update the W/E count information to the write operation and may not update the W/E count information to the erase operation. The control unit 23A may update the W/E count information to the erase operation and may not update the W/E count information to the write operation.

The write operation and the erase operation are performed on the NAND memory 30A at various timings. Accordingly, in the SSD 10A, the NAND temperature when performing the write operation and the NAND temperature when performing the erase operation may differ. In view of this, the SSD 10A may update the W/E count information to both the write operation and the erase operation. The following describes a case where the SSD 10A updates the W/E count information to any one of the write operation or the erase operation. Accordingly, one-time write/erase operation in the embodiment is one-time write operation or one-time erase operation. In the following description, write/erase means write or erase, and write/read/erase means write, read, or erase.

Usually, the one-time write/erase operation counts up the count of writes/erases by “1.” In this embodiment, when performing the one-time write/erase operation, the control unit 23A adds a value corresponding to the NAND temperature, such as “2”, “1”, and “0.5”, to the W/E count information. In other words, the value, such as “2”, “1”, and “0.5”, weighted to the count of writes/erases is added to the W/E count information. Thus, the control unit 23A adds the value to the W/E count information. The value corresponds to the count of writes/erases occurred after the previous update of the W/E count information and the NAND temperature.

For example, at a low NAND temperature (a temperature lower than a predetermined temperature), the deterioration of the NAND memory 30A is likely to proceed than usual. In view of this, at the low NAND temperature, the control unit 23A adds “1+X” (X is a value larger than 0) to the W/E count information for the one-time write/erase operation. At the low NAND temperature, the control unit 23A of this embodiment adds, for example, “2” to the W/E count information by the one-time write/erase operation. In other words, at the low NAND temperature, by the one-time write/erase operation, the control unit 23A determines that the write/erase operation is performed twice and updates the W/E count information.

At a medium NAND temperature (a temperature in the predetermined range), the deterioration of the NAND memory 30A is approximately as usual. In view of this, at the medium NAND temperature, the control unit 23A adds “1” to the W/E count information for the one-time write/erase operation. In other words, at the medium NAND temperature, by the one-time write/erase operation, the control unit 23A determines that the write/erase operation is performed once and updates the W/E count information. The medium temperature in this embodiment is, for example, room temperature.

At a high NAND temperature (a temperature higher than the predetermined temperature), the deterioration of the NAND memory 30A is less likely to proceed than usual. In view of this, at the high NAND temperature, the control unit 23A adds “1−Y” (Y is a value larger than 0) to the W/E count information for the one-time write/erase operation. At the high NAND temperature, the control unit 23A of this embodiment adds, for example, “0.5” to the W/E count information by the one-time write/erase operation. In other words, at the high NAND temperature, by the one-time write/erase operation, the control unit 23A determines that the write/erase operation is performed 0.5 times and updates the W/E count information.

The control unit 23A manages the W/E count information in the memory 24, and stores the W/E count information in the NAND memory 30A at a predetermined timing. The control unit 23A determines the degree of deterioration of the NAND memory 30A based on the W/E count information. The control unit 23A, for example, performs an operation corresponding to the degree of deterioration of the NAND memory 30A. The control unit 23A may transmit the degree of deterioration of the NAND memory 30A to the host 50.

The NAND memory 30A is configured by a semiconductor chip (SoC: System on a Chip) and a similar component. The NAND memory 30A includes a NAND IF 31, a control unit 33A, the memory 34, and the memory cell array 36. In the NAND memory 30A, the above-described respective configuration members are coupled via the bus or a similar component.

The NAND IF 31 has a function as a reception unit that accepts the write instruction, the read instruction, the erase instruction, the user data, or similar data, which is transmitted from the controller 20A. The NAND IF 31 receives data transmitted from the controller 20A (the write instruction, the read instruction, the erase instruction, the user data, or similar data). The NAND IF 31 transmits the user data (the read data) to the controller 20A.

The memory 34 is a buffer that temporarily stores the user data or similar data transmitted from the controller 20A. The memory 34 is configured using, for example, the memory retention circuit. The user data or similar data stored in the memory 34 is written to the memory cell array 36 at a predetermined timing.

The control unit 33A controls the NAND IF 31, the memory 34, and the memory cell array 36. Upon the write instruction from the controller 20A, the control unit 33A causes the memory 34 to store the user data or similar data corresponding to the write instruction. The control unit 33A writes the user data or similar data in the memory 34 to the memory cell array 36 at a predetermined timing. Upon a read instruction from the controller 20A, the control unit 33A reads the user data or similar data corresponding to the read instruction from the inside of the memory cell array 36. Upon the erase instruction from the controller 20A, the control unit 33A erases the user data or similar data corresponding to the erase instruction from the inside of the memory cell array 36.

At the memory cell array 36, cell arrays of a NAND flash-memory are arranged. The memory cell array 36 is a non-volatile memory that stores the user data transmitted from the host 50, management information regarding the SSD 10A, or similar data.

Here, the configuration of the SSD 10A when detecting the NAND temperature in the controller 20A is described. However, the NAND temperature may be detected in the NAND memory (in a NAND memory 30B described later). In other words, the NAND memory 30B may have a function corresponding to the temperature detector 22.

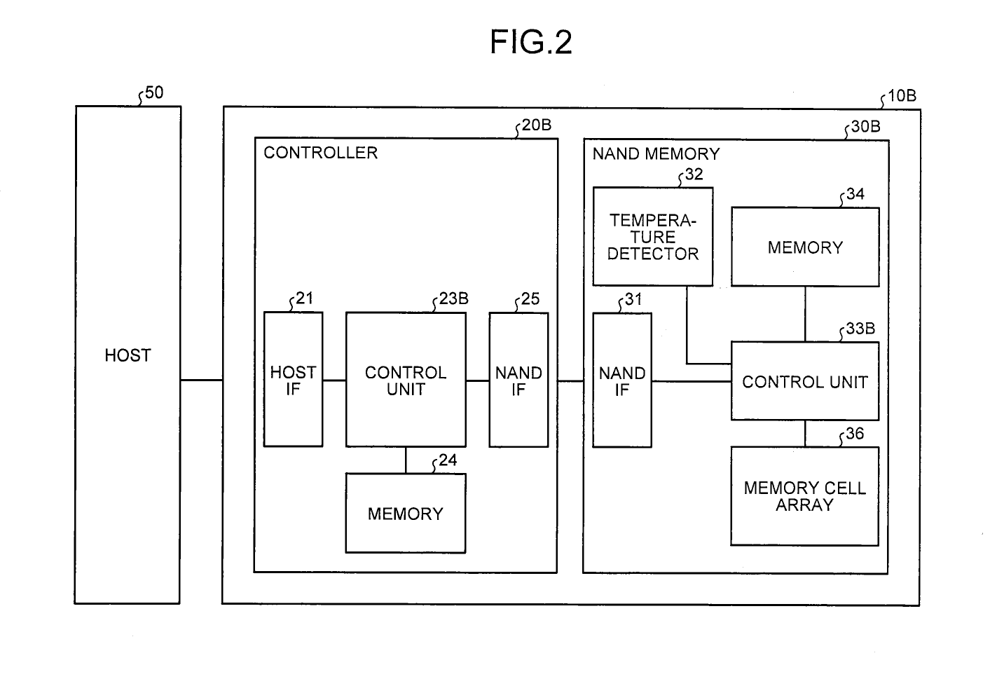

FIG. 2 is a drawing illustrating another configuration of the memory system according to the embodiment. In respective configuration members of FIG. 2, the same reference numerals are given to configuration members that achieve the same functions as those in the SSD 10A illustrated in FIG. 1, and the repeated description will be omitted correspondingly.

An SSD 10B is coupled to the external device such as the host 50. The SSD 10B includes a controller 20B and NAND memory 30B.

Upon reception of the write command, the SSD 10B writes the user data corresponding to the write command to the NAND memory 30B at a predetermined timing. Upon reception of the erase command from the host 50, the SSD 10B erases the user data corresponding to the erase command from the NAND memory 30B. Upon reception of the read command from the host 50, the SSD 10B reads the user data corresponding to the read command from the NAND memory 30B.

Similar to the SSD 10A, when writing or erasing the user data or similar data to/from the NAND memory 30A, the SSD 10B detects the temperature of the NAND memory 30B. Then, the SSD 10B weights the count of writes/erases corresponding to the detected temperature and counts up the W/E count information.

The controller 20B includes the host IF 21, a control unit 23B, the memory 24, and the NAND IF 25. The control unit 23B controls the host IF 21, the memory 24, and the NAND IF 25. The NAND memory 30B includes the NAND IF 31, a temperature detector 32, a control unit 33B, the memory 34, and the memory cell array 36.

The temperature detector 32 detects the temperature of the NAND memory 30B. The temperature detector 32 is configured using, for example, the temperature sensing circuit. The temperature detector 32, for example, detects the junction temperature when performing the write/erase operation. The junction temperature, which is detected by the temperature detector 32, is a temperature at the coupling portion of lead wires in the NAND memory 30B and members configuring the NAND memory 30B.

At occurrence of the write operation or the erase operation on the user data or similar data in the NAND memory 30B, the temperature detector 32 detects the temperature of the NAND memory 30B in accordance with an instruction from the control unit 33B. The temperature detector 32 transmits a detection result of the temperature, the NAND temperature, to the control unit 33B.

The control unit 33B controls the NAND IF 31, the temperature detector 32, the memory 34, and the memory cell array 36. At occurrence of the write/erase operation, the control unit 33B transmits the temperature detection instruction to the temperature detector 32.

Upon reception of the NAND temperature from the temperature detector 32, the control unit 33B transmits the NAND temperature to the control unit 23B. By the similar process to the control unit 23A, the control unit 23B weights the count of writes/erases and then updates the W/E count information. By the similar process to the control unit 23A, the control unit 23B determines the degree of deterioration of the NAND memory 30B. The control unit 23B manages the W/E count information in the memory 24, and stores the W/E count information in the NAND memory 30B at a predetermined timing.

The control unit 33B may update the W/E count information instead of the control unit 23B. The control unit 33B may determine the degree of deterioration of the NAND memory 30B instead of the control unit 23B. The control unit 33A may update the W/E count information instead of the control unit 23A. The control unit 33A may determine the degree of deterioration of the NAND memory 30B instead of the control unit 23A.

The following describes a procedure for operating processes of the SSDs 10A and 10B. Since the SSDs 10A and 10B operate by the similar process procedure, here, the procedure for operating processes of the SSD 10A will be described.

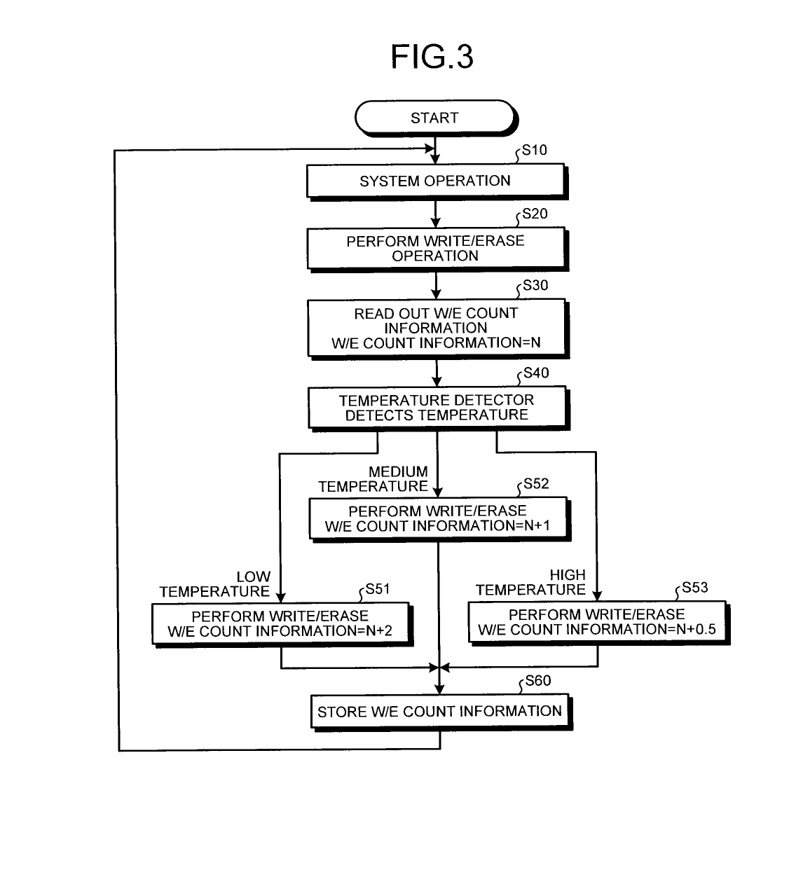

FIG. 3 is a flowchart illustrating a procedure for an operating process when the memory system according to the embodiment manages the W/E count information. At power-on, the SSD 10A starts a system operation (Step S10).

When the host 50 transmits any of the write/erase commands to the SSD 10A, the SSD 10A performs the write/erase operation (Step S20). When the write/erase operation occurs in the SSD 10A (Step S20), the control unit 23A reads the W/E count information from the NAND memory 30A or the memory 24. The W/E count information at this time is assumed as the W/E count information=N (N is a natural count) (Step S30).

The control unit 23A transmits the temperature detection instruction to the temperature detector 22. Thus, the temperature detector 22 detects the temperature of the NAND memory 30A (Step S40). When the detected temperature is a low temperature (a temperature lower than a temperature t1) (Step S40, low temperature), the control unit 23A performs the write/erase operation and updates the W/E count information to the W/E count information=N+2 (Step S51).

When the detected temperature is a medium temperature (the temperature t1 or a temperature t2) (Step S40, medium temperature), the control unit 23A performs the write/erase operation and updates the W/E count information to the W/E count information=N+1 (Step S52).

When the detected temperature is a high temperature (a temperature higher than the temperature t2) (Step S40, high temperature), the control unit 23A performs the write/erase operation and updates the W/E count information to the W/E count information=N+0.5 (Step S53).

After updating the W/E count information, the control unit 23A stores the W/E count information after the update to the NAND memory 30A or the memory 24 (Step S60). After this, the SSD 10A repeats the processes of the above-described Steps S10 to S60 until the power supply is turned OFF.

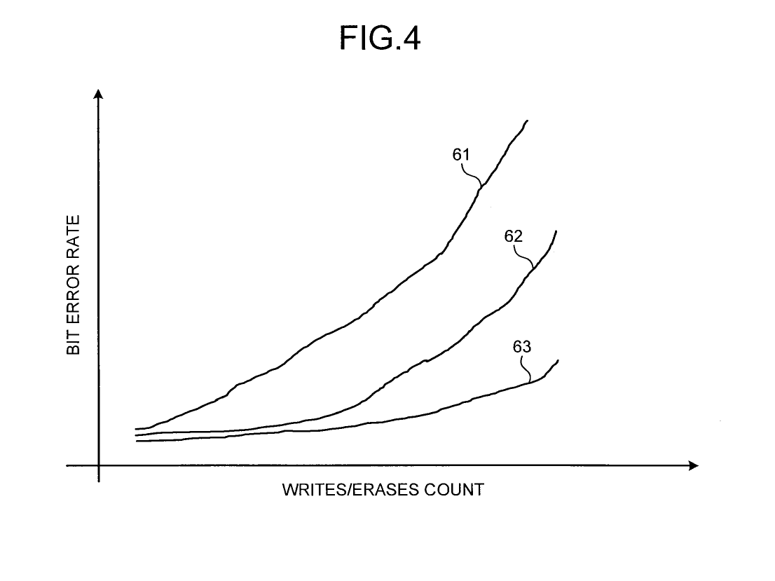

Here, the following describes a relationship between the NAND temperature and the degree of deterioration of the NAND memory 30A. FIG. 4 is a drawing for describing the relationship between the NAND temperature and the degree of deterioration of the NAND memory. The horizontal axis in FIG. 4 is the count of writes/erases of the NAND memory 30A. The vertical axis in FIG. 4 is a Bit Error Rate at the NAND memory 30A.

A property 61 is a property of the NAND memory 30A when the writes/erases are repeated at the low NAND temperature. A property 62 is a property of the NAND memory 30A when the writes/erases are repeated at the medium NAND temperature. A property 63 is a property of the NAND memory 30A when the writes/erases are repeated at the high NAND temperature.

The higher the NAND temperature is, the slower the deterioration speed of the NAND memory 30A is. On the other hand, the lower the NAND temperature is, the larger the cell stress applied to the NAND memory 30A by the write/erase is. Accordingly, the deterioration is likely to proceed.

Thus, repeated writes/erases at the low NAND temperature increases the Bit Error Rate remarkably compared with the case of the repeated writes/erases at the medium NAND temperature. Repeated writes/erases at the medium NAND temperature increases the Bit Error Rate remarkably compared with the case of the repeated writes/erases at the high NAND temperature.

The control unit 23A of this embodiment is described in the case where the NAND temperature is classified into any of the low temperature, the medium temperature, and the high temperature. However, the NAND temperature may be classified into two temperature ranges or may be classified into four or more temperature ranges.

The control unit 23A counts up the W/E count information using, for example, an information table where a temperature and a value added to the W/E count information are made correspond to one another.

The control unit 23A may calculate the value added to the W/E count information using a predetermined expression. In this case, the control unit 23A, for example, calculates the value added to the W/E count information (the additional value) using the following expression (1).

Additional value=(reference temperature−NAND temperature)/T+1 (1)

The reference temperature is, for example, a temperature such as 25 degrees, and is preliminarily set. T in the expression (1) is any given value and is preliminary set.

For example, if the W/E count information exceeds a predetermined threshold, the SSD 10A changes a NAND parameter used for controlling the NAND memory 30. The SSD 10A may change the NAND parameter corresponding to the value of the W/E count information. For example, if the W/E count information exceeds a first threshold, the SSD 10A changes the NAND parameter to a first NAND parameter. For example, if the W/E count information exceeds a second threshold, the SSD 10A changes the NAND parameter to a second NAND parameter.

The control unit 23A, for example, uses the information table where the W/E count information is made correspond to the value of the NAND parameter to calculate the value of the NAND parameter. The control unit 23A may calculate the value of the NAND parameter using a predetermined expression. The NAND parameter is a parameter that specifies the write/erase operation on the NAND memory 30. The NAND parameter is, for example, a voltage value, a pulse width, the count of pulses, or a similar specification of a pulse voltage to be applied to the memory cell in the memory cell array 36 during the write/erase operation.

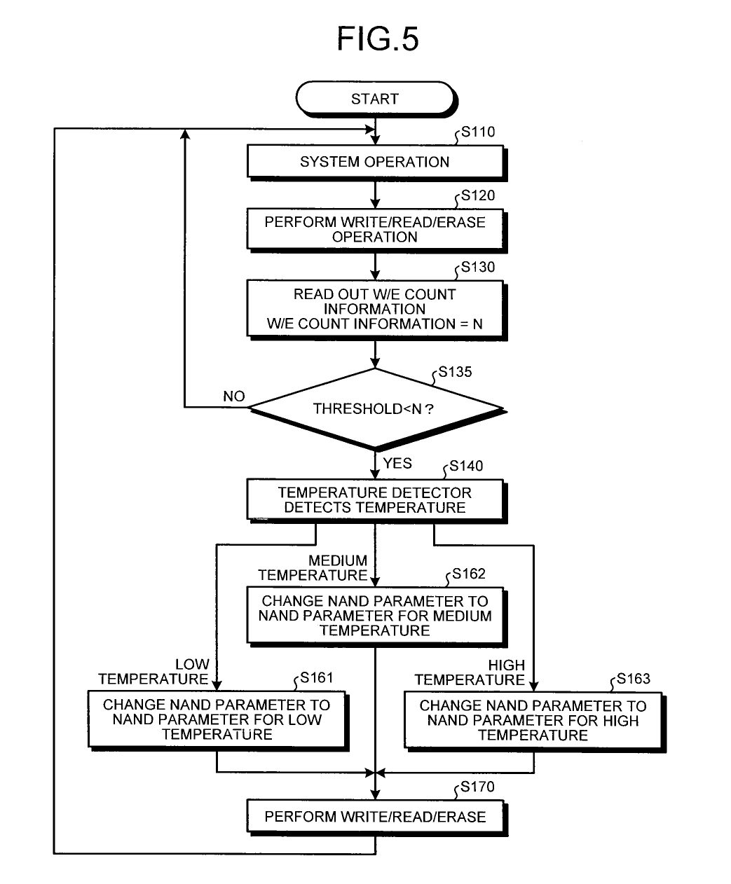

FIG. 5 is a flowchart illustrating a procedure for an operating process when the memory system according to the embodiment changes the NAND parameter. Among the respective processes in FIG. 5, the processes similar to the processes illustrated in FIG. 3 will not be further elaborated here.

At power-on, the SSD 10A starts the system operation (Step S110). When the host 50 transmits any of the write/read/erase commands to the SSD 10A, the SSD 10A performs the write/read/erase operation (Step S120). When the write/read/erase operation occurs in the SSD 10A, the control unit 23A reads the W/E count information from the NAND memory 30A or the memory 24. The W/E count information at this time is assumed as the W/E count information=N (N is a natural count) (Step S130).

The control unit 23A determines whether the W/E count information is larger than a predetermined threshold or not. Specifically, the control unit 23A determines whether the threshold<N or not (Step S135). When the threshold N (No at Step S135), the SSD 10A continues the system operation (Steps S110 to S130). The control unit 23A determines whether the threshold<N or not (Step S135). When the threshold<N (Yes at Step S135), the control unit 23A turns ON an Adaptive function. The Adaptive function is a function to change the NAND parameter. When the threshold<N, the control unit 23A transmits the temperature detection instruction to the temperature detector 22.

Accordingly, the temperature detector 22 detects the temperature of the NAND memory 30A (Step S140). When the detected temperature is a low temperature (a temperature lower than a temperature t11) (Step S140, low temperature), the control unit 23A changes the NAND parameter in use to the NAND parameter for low temperature (Step S161). When the detected temperature is the low temperature, the control unit 23A, for example, shortens the data writing time to the NAND memory 30A than usual. If the NAND parameter in use has already been changed to the NAND parameter for low temperature, the NAND parameter needs not to be changed.

When the detected temperature is a medium temperature (the temperature t11 or a temperature t12) (Step S140, the medium temperature), the control unit 23A changes the NAND parameter in use to the NAND parameter for medium temperature (Step S162). If the NAND parameter in use has already been changed to the NAND parameter for medium temperature, the NAND parameter needs not to be changed.

When the detected temperature is a high temperature (a temperature higher than the temperature t12) (Step S140, high temperature), the control unit 23A changes the NAND parameter in use to the NAND parameter for high temperature (Step S163). When the detected temperature is the high temperature, the control unit 23A, for example, lengthens the data writing time to the NAND memory 30A than usual. If the NAND parameter in use has already been changed to the NAND parameter for high temperature, the NAND parameter needs not to be changed.

After changing the NAND parameter, the control unit 23A performs the write/read/erase operation using the NAND parameter after the change (Step S170). In this case, the control unit 23A may add the value corresponding to the NAND temperature to the W/E count information. After this, the SSD 10A repeats the processes of the above-described Steps S110 to S170 until the power supply is turned OFF.

With the SSD 10A, the larger the W/E count information is, the more the deterioration of the NAND memory 30A proceeds. In the case where the W/E count information is larger than the predetermined threshold of the W/E count information, this embodiment changes the NAND parameter to the NAND parameter corresponding to the NAND temperature. In view of this, even if the deterioration of the NAND memory 30A proceeds, temperature dependence of the NAND memory 30A is canceled. This allows reducing a deterioration of the property of the NAND memory 30A, allows improving reliability of the NAND memory 30A.

The control unit 23A may change the NAND parameter to a value corresponding to an amount of Error Correction Code (ECC) correction when reading the NAND parameter. In this case, based on the corresponding information that makes the amount of ECC correction correspond to the NAND parameter, the control unit 23A changes the NAND parameter.

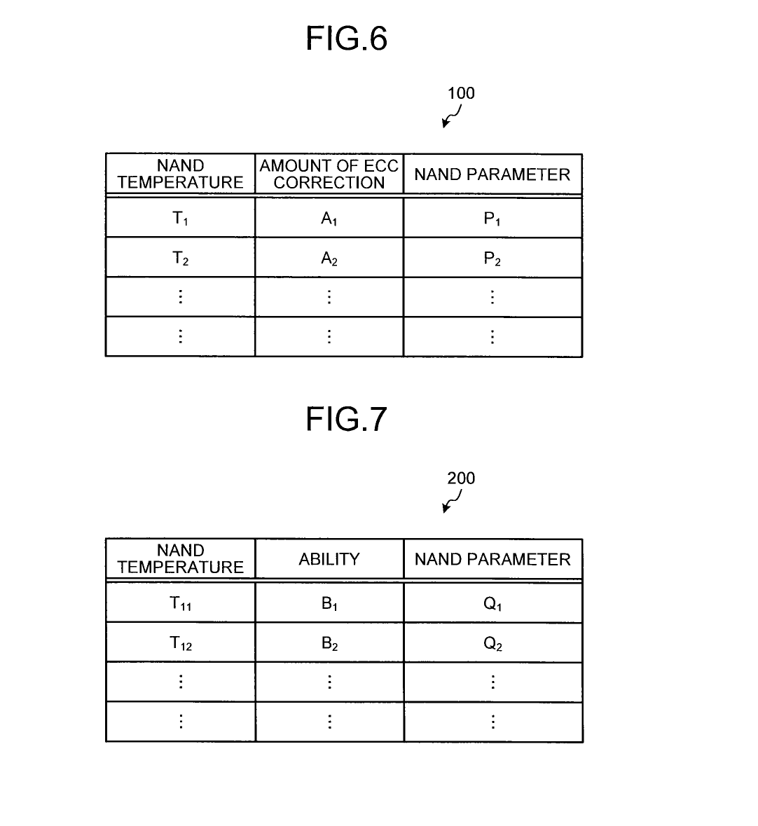

FIG. 6 is a drawing illustrating exemplary corresponding information that makes the amount of ECC correction correspond to the NAND parameter. The NAND memory 30A or a similar memory internally stores corresponding information 100, which makes the amount of ECC correction correspond to the NAND parameter, preliminarily.

The corresponding information 100 makes the NAND temperature, the amount of ECC correction, and the NAND parameter correspond to one another. For example, T₁ of the NAND temperature, A₁ of the amount of ECC correction, and P₁ of the NAND parameter are made correspond to one another. In this case, when the NAND temperature is T₁ and the amount of ECC correction during reading is A₁, the control unit 23A changes the NAND parameter to P₁.

Thus, setting the NAND parameter corresponding to the NAND temperature and the amount of ECC correction allows improving the reliability of the NAND memory 30A. The NAND temperature T₁, T₂, or a similar value in the corresponding information 100 may be a predetermined temperature range. The amount of ECC correction A₁, A₂, or a similar value in the corresponding information 100 may be the amount of correction in a predetermined range. If the change in the NAND parameter reduces the amount of ECC correction to a predetermined amount, the control unit 23A may keep using the changed NAND parameter.

The control unit 23A may change the NAND parameter to a value corresponding to the ability of the NAND memory 30A. In this case, the control unit 23A changes the NAND parameter based on the corresponding information, which makes the ability of the NAND memory 30A correspond to the NAND parameter.

FIG. 7 is a drawing illustrating exemplary corresponding information that makes an ability of the NAND memory correspond to the NAND parameter. The NAND memory 30A or a similar memory internally stores corresponding information 200, which makes the ability of the NAND memory 30A correction correspond to the NAND parameter, preliminarily.

The corresponding information 200 makes the NAND temperature, the ability of the NAND memory 30A, and the NAND parameter correspond to one another. For example, T₁₁ of the NAND temperature, B₁ of the ability of the NAND memory 30A, and Q₁ of the NAND parameter are made correspond to one another. In this case, when the NAND temperature is T₁₁ and the ability of the NAND memory 30A is B₁, the control unit 23A changes the NAND parameter to Q₁. The NAND temperature T₁₁, T₁₂, or a similar value in the corresponding information 200 may be a predetermined temperature range. The ability B₁, B₂, or a similar value in the corresponding information 200 may be the ability in a predetermined range.

The ability of the NAND memory 30A is, for example, a current value or a similar specification required for the write/read/erase operation. The ability of the NAND memory 30A depends on the ability of the semiconductor chips arranged in the NAND memory 30A. In view of this, the ability of the NAND memory 30A in the corresponding information 200 is, for example, set to each lot (each lot number) of the semiconductor chips arranged in the NAND memory 30A.

Thus, the NAND parameter corresponding to the NAND temperature and the ability of the NAND memory 30A is set. This allows improving the reliability of the NAND memory 30A even if a production tolerance occurs in the chips configuring the NAND memory 30.

At wear leveling, the control unit 23A may decide a movement destination of data based on the W/E count information and the NAND temperature during a writing process. The wear leveling is a process that equally disperses data writing positions to reduce a variation of the count of data writes/erasures in the NAND memory 30A. In other words, the wear leveling is a process to physically prevent concentrated writings to the identical address. Execution of the wear leveling allows smoothing an abrasion in the NAND memory 30A.

As described above, the SSD 10A, which is the memory system, includes the NAND memory 30A, which is the non-volatile memory. The SSD 10A includes the controller 20A that controls the NAND memory 30A. The SSD 10A includes the temperature detector 22 that detects the NAND temperature when performing a write process or an erase process on the NAND memory 30A. Then, the controller 20A manages the W/E count information, which indicates the value regarding the count of writes or the count of erases in the NAND memory 30A, in each predetermined region in the NAND memory 30A. Furthermore, the controller 20A adds the value corresponding to the detected temperature to the W/E count information. The controller 20A determines the degree of deterioration of the NAND memory 30A based on the W/E count information after the addition.

Accordingly, this embodiment can determine the deterioration of the NAND property corresponding to the NAND temperature. This allows accurate determination of the deterioration of the property of the NAND memory 30A. This allows improving the reliability of the SSD 10A.

When the W/E count information exceeds the threshold, the SSD 10A changes the NAND parameter to the one corresponding to the NAND temperature. Accordingly, even if the deterioration of the NAND memory 30A proceeds, the NAND property can be maintained or improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system connectable to an external device, comprising:
a non-volatile memory;
a control unit configured to control the non-volatile memory in response to a request from the external device, the control unit being configured to manage count information in each predetermined region in the non-volatile memory, the count information relating to a count of writes or a count of erases in the non-volatile memory; and
a temperature detector configured to detect a first temperature in the memory system, wherein
the control unit is configured to add a value to the count information, the added value corresponding to the count of writes or the count of erases occurred after a previous update of the count information and the first temperature, the control unit being configured to determine a degree of deterioration of the non-volatile memory based on the count information after the addition.

2. The memory system according to claim 1, wherein
the control unit is configured to add a first additional value as the added value to the count information in a case where the first temperature is a first value, and the control unit is configured to add a second additional value smaller than the first additional value as the added value to the count information in a case where the first temperature is a second value larger than the first value.

3. The memory system according to claim 1, wherein
the control unit is configured to change a control parameter used for controlling the non-volatile memory in a case where the count information exceeds a predetermined threshold.

4. The memory system according to claim 1, wherein
the temperature detector is configured to detect a second temperature in a case where the count information exceeds a predetermined threshold, and
the control unit is configured to change a control parameter to a value corresponding to the second temperature, the control parameter being used for controlling the non-volatile memory.

5. The memory system according to claim 4, wherein
the control unit is configured to compare the count information with the predetermined threshold upon reception of any of a write command, a read command, and an erase command.

6. The memory system according to claim 5, wherein
the control unit is configured to use the control parameter when performing a process corresponding to a received write command, read command, or erase command.

7. The memory system according to claim 4, wherein
the control unit is configured to change the control parameter based on an amount of ECC correction when reading data from the non-volatile memory and the second temperature.

8. The memory system according to claim 1, wherein
the control unit is configured to decide a movement destination of data subject to wear leveling based on the count information and the first temperature at the wear leveling.

9. The memory system according to claim 1, wherein
the temperature detector is arranged in a semiconductor chip where the control unit is arranged.

10. The memory system according to claim 1, wherein
the control unit is configured to change a control parameter based on a magnitude of the count information, the control parameter being used for controlling the non-volatile memory.

11. The memory system according to claim 1, wherein
the temperature detector is arranged in a semiconductor chip where the non-volatile memory is arranged.

12. The memory system according to claim 1, wherein
the control unit is configured to calculate a value corresponding to the temperature using a predetermined expression.

13. A controller connectable to an external device, comprising
a control unit configured to control a non-volatile memory in response to a request from the external device, the control unit being configured to manage count information in each predetermined region in the non-volatile memory, the count information relating to a count of writes or a count of erases in the non-volatile memory, wherein
the control unit is configured to add a value to the count information, the added value corresponding to the count of writes or the count of erases occurred after a previous update of the count information and a first temperature in the memory system, the control unit being configured to determine a degree of deterioration of the non-volatile memory based on the count information after the addition.

14. The controller according to claim 13, wherein
the control unit is configured to add a first additional value as the added value to the count information in a case where the first temperature is a first value, and the control unit is configured to add a second additional value smaller than the first additional value as the added value to the count information in a case where the first temperature is a second value larger than the first value.

15. The controller according to claim 13, wherein
the control unit is configured to change a control parameter used for controlling the non-volatile memory in a case where the count information exceeds a predetermined threshold.

16. The controller according to claim 13, wherein
a second temperature is detected in a case where the count information exceeds a predetermined threshold, and
the control unit is configured to change a control parameter to a value corresponding to the second temperature, the control parameter being used for controlling the non-volatile memory.

17. The controller according to claim 16, wherein
the control unit is configured to compare the count information with the predetermined threshold upon reception of any of a write command, a read command, and an erase command.

18. The controller according to claim 17, wherein
the control unit is configured to use the control parameter when performing a process corresponding to a received write command, read command, or erase command.

19. The controller according to claim 16, wherein
the control unit is configured to change the control parameter based on an amount of ECC correction when reading data from the non-volatile memory and the second temperature.

20. The controller according to claim 13, wherein
the control unit is configured to decide a movement destination of data subject to wear leveling based on the count information and the first temperature at the wear leveling.
